(19) United States
(12) Patent Application Publication
(10) Pub. No.: US 2008/0016486 A1
(43) Pub. Date: Jan. 17, 2008

(54) System and method of assessing reliability of a semiconductor

(76) Inventors: Yuen Liu Chan, Singapore (SG); Yong Han Frankie Low, Singapore (SG); Yue Wen Huang, Singapore (SG); Kok Siong Goh, Singapore (SG); Kok Tong Tan, Singapore (SG)

Correspondence Address: GOODWIN PROCTER L.L.P, 599 LEXINGTON AVE., NEW YORK, NY, 10022, US

(21) Appl. No.: 11/417,451

(22) Filed: May 3, 2006

(51) Int. Cl. G06F 17/50; H03K 19/00; H01L 21/66; G01R 31/26

(52) U.S. Cl. 716/17; 438/15

(57) ABSTRACT

A system for assessing reliability of a semiconductor product design, the system comprising a first database for storing circuits data specifying cells of available circuits for semiconductor products; an input unit for input of reliability qualification data of tested semiconductor products; an uploading unit for uploading semiconductor product design data; and a processor for processing the reliability qualification data to generate reliability data at a circuit-level, a cell-level, or both utilizing the circuits data, and for assessing the reliability of the semiconductor product design based on the generated reliability data.

### PRODUCT DESIGN FIELD OF INVENTION

The invention relates broadly to a system for assessing reliability of a semiconductor product design, to a method of assessing reliability of a semiconductor product design and to a computer readable data storage medium having stored thereon computer code means for instructing a computer processor to execute a method of assessing reliability of a semiconductor product design.

### BACKGROUND

In the semiconductor manufacturing industry, for a new product such as an integrated chip, there is typically insufficient information to assess the reliability of the product until reliability qualification is carried out.

Reliability qualification is a procedure where specific reliability tests are performed to assess the characteristics of the product. These reliability tests may comprise a Highly Accelerated Stress Test (HAST), a High Temperature Operating Life (HTOL) test, Temperature-Humidity-Bias (THB) test, a Temperature Cycling (TMCL) test, a Dynamic High Temperature Life (DHTL) test, an Electro Static Discharge (ESD) test, an ESD Human Body Model (ESD HBM) test, an ESD Machine Model (ESD MM) test and a Latch-Up (LAUP) test.

By carrying out reliability qualification after the product is manufactured, one problem may arise that product reliability failure discovered during reliability qualification typically leads to a delay in time-to-market. Also, even with reliability data obtained by reliability qualification, the reliability of the circuits making up the complete product typically cannot be fully assessed.

Hence, there exists a need for a system and method of assessing reliability of the semiconductor product design to address the above problem.

### SUMMARY

In accordance with a first aspect of the present invention, there is provided a system for assessing reliability of a semiconductor product design, the system comprising: a first database for storing circuits data specifying cells of available circuits for semiconductor products; an input unit for input of reliability qualification data of tested semiconductor products; an uploading unit for uploading semiconductor product design data; and a processor for processing the reliability qualification data to generate reliability data at a circuit-level, a cell-level, or both utilizing the circuits data, and for assessing the reliability of the semiconductor product design based on the generated reliability data.

The system may further comprise a second database for storing the generated reliability data.

The generated reliability data may be stored in the form of a lookup table.

The processor may segregate the semiconductor product design into circuits, cells or both for assessing the reliability of the semiconductor product design based on the generated cell-level reliability data.

The input means may be a Graphical User Interface (GUI).

The system may further comprise a report generator module for outputting reports based on the assessed reliability of the semiconductor product design.

The system may further comprise an output Graphical User Interface (GUI) for display.

The processor may comprise a security management module for managing user access to the system.

The system may further comprise an editing module for editing the circuits data based on a user input.

The uploading unit may be a file uploader application program.

In accordance with a second aspect of the present invention, there is provided a method of assessing reliability of a semiconductor product design, the method comprising: storing circuit data specifying cells of available circuits for semiconductor products; inputting reliability qualification data of tested semiconductor products; uploading semiconductor product design data; processing the reliability qualification data to generate reliability data at a circuit-level, a cell-level, or both utilizing the circuit data; and assessing the reliability of the semiconductor product design based on the generated reliability data.

The method may further comprise linking the circuit data with statistical information based on a product status.

In accordance with a third aspect of the present invention, there is provided a computer readable data storage medium having stored thereon computer code means for instructing a computer processor to execute a method of assessing reliability of a semiconductor product design, the method comprising: storing circuit data specifying cells of available circuits for semiconductor products; inputting reliability qualification data of tested semiconductor products; uploading semiconductor product design data; processing the reliability qualification data to generate reliability data at a circuit-level, a cell-level, or both utilizing the circuit data; and assessing the reliability of the semiconductor product design based on the generated reliability data.

### BRIEF DESCRIPTION OF THE DRAWINGS

Embodiments of the invention will be better understood and readily apparent to one of ordinary skill in the art from the following written description, by way of example only, and in conjunction with the drawings, in which:

FIG. 1 is a schematic diagram illustrating a system for assessing reliability of a semiconductor product design.

FIG. 2 illustrates a reliability template in a lookup table form.

FIG. 3 is a schematic system diagram illustrating a Central Processing Unit (CPU).

FIG. 4 is a schematic modular diagram illustrating various application programs implemented in a system for assessing reliability of a semiconductor 20 product design.

FIG. 5 is an example of product hierarchical data.

FIG. 6 illustrates two reliability templates in lookup table form, 25.

FIG. 7 illustrates two lookup tables for statistically assessing reliability at different product statuses.

FIG. 8 is a flowchart illustrating a method of assessing reliability of a 30 semiconductor product design.

### DETAILED DESCRIPTION

The following is a definition of some terms used in the description. A cell is defined as the basic building block of a circuit or a semiconductor product. In other words, a circuit may generally comprise a plurality of cells. Thus, when referring to a product, the circuits of the product may each comprise a plurality of product cells. In the description, a circuit is a building block of a product. An example of a circuit is a solid-state memory device such as a Random Access Memory (RAM) module.

Some portions of the description which follows are explicitly or implicitly presented in terms of algorithms and functional or symbolic representations of operations on data within a computer memory. These algorithmic descriptions and functional or symbolic representations are the means used by those skilled in the data processing arts to convey most effectively the substance of their work to others skilled in the art. An algorithm is here, and generally, conceived to be a self-consistent sequence of steps leading to a desired result. The steps are those requiring physical manipulations of physical quantities, such as electrical, magnetic or optical signals capable of being stored, transferred, combined, compared, and otherwise manipulated.

Unless specifically stated otherwise, and as apparent from the following, it will be appreciated that throughout the present specification, discussions utilizing terms such as “transmitting”, “retrieving”, “storing”, “inputting”, “generating”, “analyzing”, “processing”, “outputting”, or the like, refer to the action and processes of a computer system, or similar electronic device, that manipulates and transforms data represented as physical quantities within the computer system into other data similarly represented as physical quantities within the computer system or other information storage, transmission or display devices.

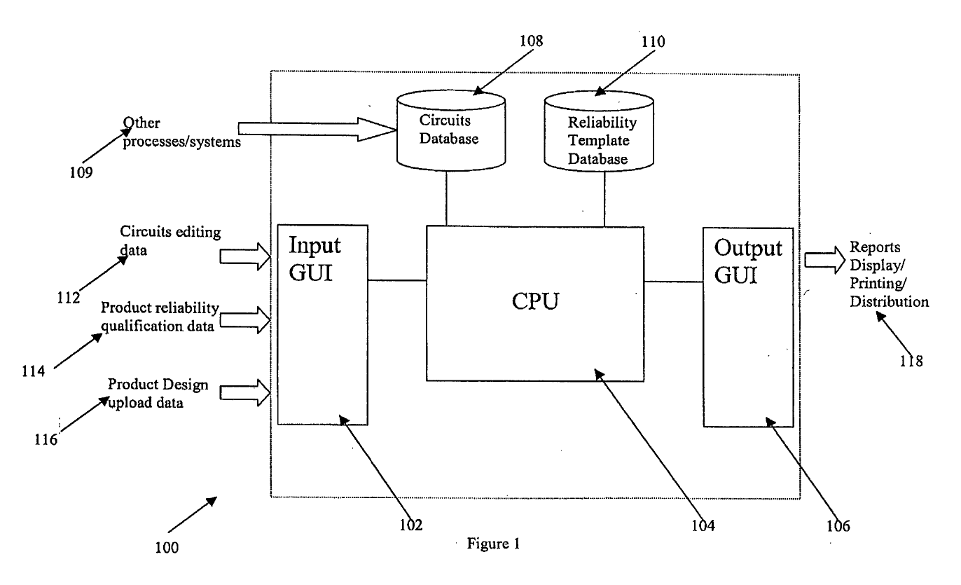

FIG. 1 is a schematic diagram illustrating a system 100 for assessing reliability of a semiconductor product design. The system 100 comprises an input Graphical User Interface (GUI) 102 coupled to a Central Processing Unit (CPU) 104, an output GUI 106 coupled to the CPU 104, a circuits database 108 coupled to the CPU 104 and a reliability template database 110 coupled to the CPU 104. In the system 100, population of the circuits database 108 can occur from other processes/systems indicated at numeral 109. The system 100 receives input data via the input GUI 102. The input data comprises circuits editing data indicated at 5 numeral 112, product reliability qualification data indicated at numeral 114 and product design upload data indicated at numeral 116. The product design upload data may comprise e.g. a new semiconductor product design and reliability assessment is to be carried out on the new product design on the system 100.

In the following description, the processing of the CPU 104 is described firstly with regards to the circuits editing data received via the GUI 102 and then with regards to the product reliability qualification data received via the GUI 102.

The CPU 104 retrieves and edits circuits data from the circuits database 108 based on the circuits editing data received via the GUI 102. An example of the editing may be assigning a circuit name or revision number to a piece of circuits data in the circuits database 108.

The CPU 104 constructs and/or populates the reliability template database 110 based on the circuits data in the circuits database 108 and the product reliability qualification data received via the GUI 102. The reliability template database 110 stores reliability data in one or more reliability templates. The contents of the reliability templates are based on the circuits data in the circuits database 108 and the product reliability qualification data received via the GUI 102.

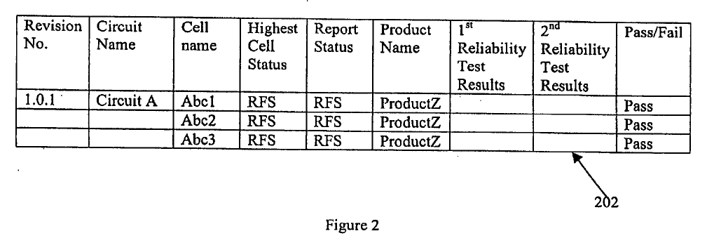

FIG. 2 illustrates a reliability template in a lookup table 202 form. The lookup table 202 comprises tabulated information such as the revision number of the circuit (data field: Rev), the circuit name (data field. circuit name), the cells of the circuit (data field: Cell Name), the highest status of the circuit used in existing products (data field: Highest Cell Status), the current report: status (data field: Report Status), the product using the circuit (data field: Product Name), columns displaying results of different reliability tests (data fields: 1s′ Test Results and 2″d Test Results) and the product reliability qualification pass/fail result based on the reliability tests (data field: Pass/Fail).

Referring back to FIG. 1, when the system receives a semiconductor product design for assessment via the GUI 102, the CPU 104 performs reliability assessment processing based on statistical calculations of the reliability data stored in reliability template database 110 on the one hand and the product design upload data on the other hand. Details of the reliability assessment will be described below.

The CPU 104 outputs the reliability assessment results via the output GUI 106. The output at the output GUI 106 may be in the form of generated reports for display, for printing or for electronic distribution indicated at numeral 118.

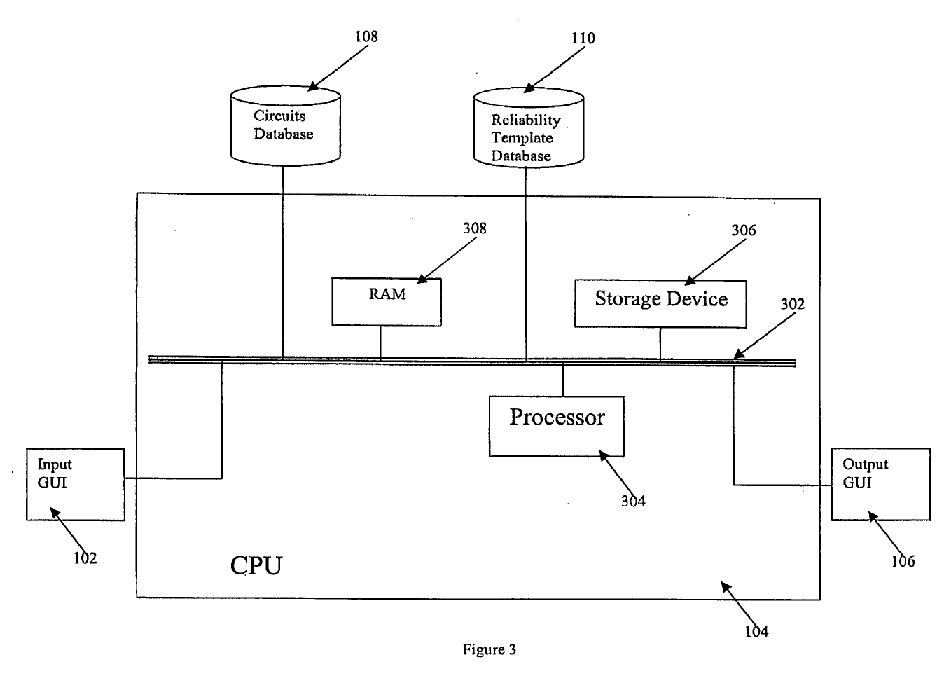

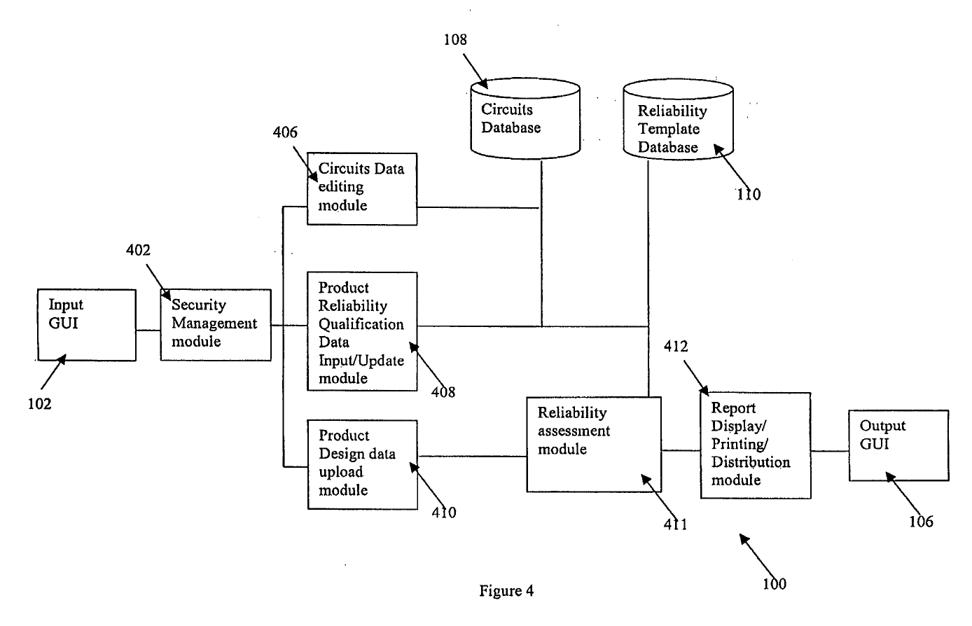

FIG. 3 is a schematic system diagram illustrating the CPU 104 of FIG. 1. The CPU 104 comprises a communication bus 302, a processor 304 coupled to the communication bus 302, a storage device 306 coupled to the communication bus 302 and a Random Access Memory (RAM) chip 308 coupled to the communication bus 302. In addition, the communication bus 302 provides coupling to the input GUI 102, the output GUI 106, the circuits database 108 and the reliability template database 110. The communication bus 302 enables communication between the coupled elements. The RAM 308 comprises computer code for the CPU 104 to operate and the processor 304 executes processing. for the CPU 104. The storage device 306 stores a number of application programs written for execution by the processor 304. The function of the application programs will be described below in more detail with reference to FIG. 4.

FIG. 4 is a schematic modular diagram illustrating the various application programs implemented in the CPU 104 of FIG. 3. A security management module 402 is implemented as a log-in access via the input GUI 102 to enforce a “user account and password” scheme as different users may possess different system access capabilities. For example, the security management module 402 may allow read/write or read only access to the system 100 based on a user's security clearance.

A circuits data editing module 406 is implemented to edit the circuits data stored in the circuits database 108 based on the circuits editing data received via the GUI 102. The editing process comprises assigning identification information, such as circuit name or revision number, to the circuits data in the circuits database 108. The circuits editing data received via the GUI 102 may comprise information such as product identification, product nickname and product technology node. For example, the product technology node for the circuits data of the product may indicate that the product is of 140 nm technology. The circuits data editing module 406 updates the edited circuits data into the circuits database 108.

A product reliability qualification data input/update module 408 is implemented to input new product reliability qualification data or update existing product reliability qualification data based on the product reliability qualification data received via the GUI 102 into the system 100. The reliability qualification data may comprise information such as product name, reliability test name, reliability test conditions, reliability test results and product status. The product status comprises statuses such as tapeout”, “Customer Qualification Samples (CQS)” or “Release for Supply (RFS)”. The product reliability qualification data input/update module 408 populates the reliability template database 110 based on the reliability qualification data received and based on the circuits database 108. More particularly, utilizing the circuits database 108, circuits and cells in the product to which the reliability qualification data relates are identified and allocated with reliability data based on the product reliability qualification data received via the GUI 102. The reliability template database 110 is thus populated at a cell-level (compare the lookup table 202 in FIG. 2).

A product design data upload module 410 is implemented to upload a product 30 design into the CPU 104. In this arrangement, the product design is in Graphical Design System II (GDS II) form and loaded via Xref file format. Each GDS II Xref file comprises the cells used in the product design and product hierarchical data relating to the product design. The product hierarchical data comprises hierarchical segregation of the circuits contained in the product design into basic cells.

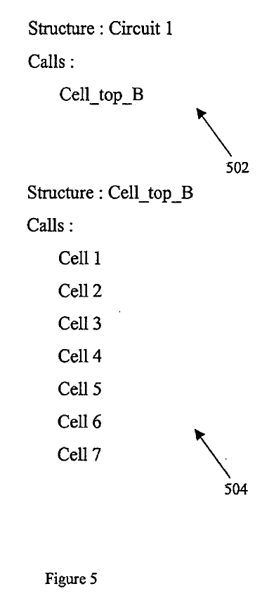

FIG. 5 is an example of the product hierarchical data. The root node of the product hierarchy indicated at numeral 502 comprises data of a root structure (i.e., Circuit 1) and the relevant cell data of Circuit 1 (i.e. Cell top_B). At numeral 504, the structure Cell top_g is segregated further into tree nodes (i.e., basic Cells 1 to 7) of the product hierarchy.

Referring back to FIG. 4, the product design data upload module 410 extracts information, such as product identification, product nickname and product technology node, from the product design and generates product hierarchical trees in the product technology node. Thus, the product design data upload module 410 identifies and segregates the product design into a cell-level.

A reliability assessment module 411 is implemented to perform statistical analysis processing on the reliability template database 110 for extracting reliability data based on the cell-level information from the product design data upload module 410. Since both the reliability template database 110 and the uploaded product design are processed at a product cell level, it will be appreciated that the system can advantageously provide more detailed cell-level reliability data, compared to assessing the reliability of a new product design based on the native reliability qualification data.

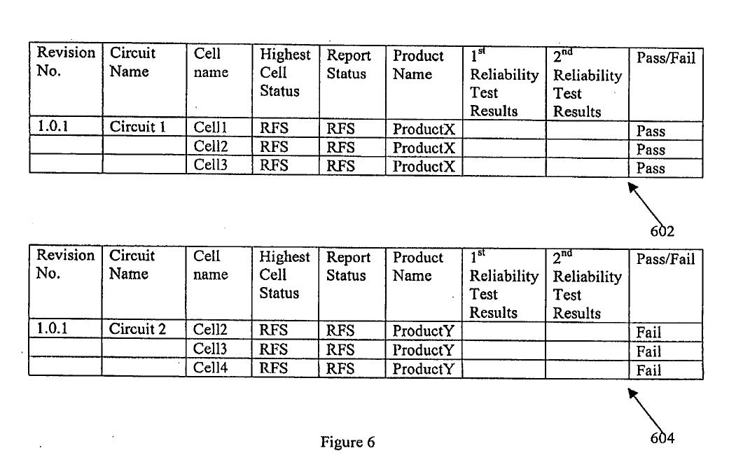

In the following, a simple example of the statistical analysis processing to extract cell-level reliability data from the reliability template database 110 is provided with reference to FIG. 6. FIG. 6 illustrates two stored lookup tables 602 and 604. Assume that a product design to be assessed includes, amongst other components, Cell 1, Cell 2 and Cell 4.

From the lookup table 602, it is derived that since Product X passed reliability qualification, the cells Cell 1, Cell 2 and Cell 3 which form circuit 1 used in Product X have also been allocated a pass result at cell-level. On the other hand, from the lookup table 604, it is derived that since Product Y failed reliability qualification, the cells Cell 2, Cell 3 and Cell 4 which form circuit 2 used in Product Y have also been allocated a fail result at cell-level. Therefore, as a result of the statistical analysis processing of the lookup tables 602 and 604, Cell 4 can be isolated as a likely failing component in the new product design.

It would be appreciated by a person skilled in the art that this extracted reliability information about Cell 4 provides more detailed cell-level reliability data, compared to assessing the reliability of the new product design based on the native reliability qualification data. Also, while only two reliability templates are shown here for illustration purposes, it would be appreciated by a person skilled in the art that, more reliability templates may be used to more accurately assess the reliability of the product cells. Generally, as the number of reliability templates used increases, so should the reliability of the assessment.

Furthermore, as an alternative or in addition to the statistical analysis processing as illustrated with reference to FIG. 6, the reliability assessment module 411 performs statistical analysis processing on the reliability template database 110 for extracting reliability data based on different product statuses.

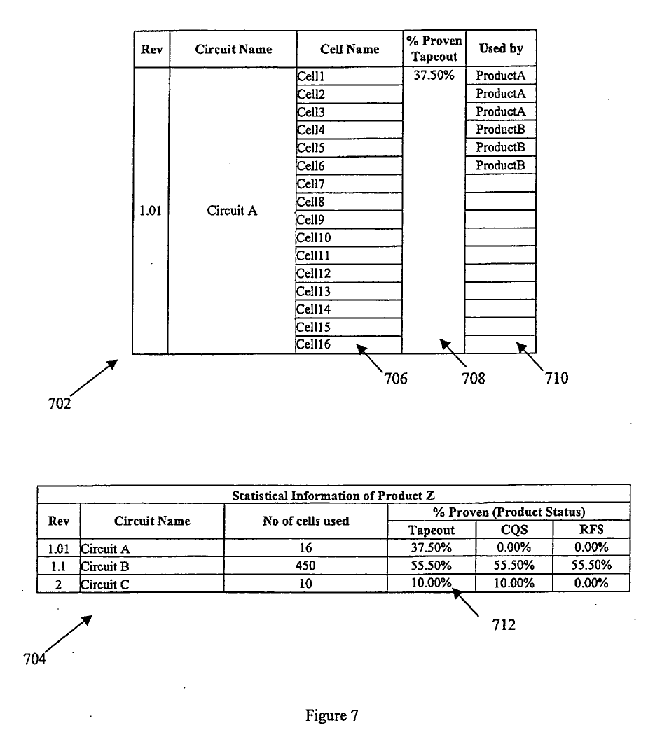

In the following, a simple example of the statistical analysis processing to extract reliability data based on different product statuses from the reliability template database 110 is provided with reference to FIG. 7.

FIG. 7 illustrates a cell-level lookup table 702 and a circuit-level lookup table 704. The lookup table 702 shows a Circuit A (at revision 1.01) having a total of 16 cells in column 706. The statistical reliability result of the 16 cells at the product status of Tapeout is shown in column 708. The different products using the same cells are shown in column 710.

The statistical reliability result of 37.5% as shown in column 708 is derived from statistical analysis where it is indicated that 37.5% of the 16 cells have been “proven” (or passed reliability qualification) at the Tapeout product status. The statistical analysis is performed based on reliability qualification results of the cells used by different products shown in column 710 at the same product status (i.e. Tapeout). The statistical analysis result of 37.5% is then updated in the product circuit-level lookup table 704.

In this example, the lookup table 704 shows the statistical circuit-level information of a new Product Z and the Product Z comprises the above Circuit A, a Circuit B and a Circuit C. As shown in column 712, at the Tapeout product status, the Circuit A is shown to have statistical reliability result of 37.5%. In other words, from lookup table 704, it may be seen that at Tapeout product status, Circuit A is 37.5% likely to pass while Circuit C is only 10% likely to pass.

In the current arrangement, RFS is the highest achievable product status and the stored statistics in relation to the RFS product status take precedence over other product statuses. Thus, if a particular circuit has been “proven” at RFS product status, the statistics are also reflected at the CQS and tapeout statuses.

Therefore, table 704 summarizes statistical reliability data at the different product statuses for a product design.

It would be appreciated by a person skilled in the art that although circuit-level reliability data at different product statuses is used for statistical analysis processing in this example, cell-level reliability data at different product statuses may also be stored and extracted for analysis using the method as described in this example.

Returning back to FIG. 4, the statistical analysis results of the reliability assessment module 411 may generally indicate either a percentage of a confidence level for reliability (e.g. 50% of product cells likely to pass) or a percentage of the area of coverage of the product design that can be assessed since some circuits identified from the product design may not have corresponding existing product reliability qualification data stored in the system (e.g. 90% of product assessed for reliability).

While the above description has been focusing on cell-level reliability assessment, it would be appreciated that the system may additionally or alternatively perform the assessment at a circuit-level. Again, like the cell-level information discussed above, the circuit-level reliability data provides useful information, compared to assessing the reliability of the new product design based on the native reliability qualification data.

A report display/printing/distribution module 412 is implemented to generate a report such as a report for known circuits/cell reliability data stored in the system 100 or a report for assessed product/product circuits reliability data. The report display/printing/distribution module 412 outputs the report via the output GUI 106 (FIG. 1). The generated reports may comprise matter such as percentage reliability assessments of products, percentage coverage in silicon for the products and updated reliability assessments of products with new product reliability data input. In addition, the report display/printing/distribution module 412 via the output GUI 106 (FIG. 1) also displays circuits information of each product at a chosen status such as at Tapeout, CQS or RFS. This information comprises cell information, reliability test results and reliability test status of the product. The report may either be in Hyper-Text Marked-Up Language (HTML) or Microsoft Excel format and the report data fields may be customized according to the user's requirements. The output at the GUI 106 (FIG. 1) may be in the manner of a display or a printing of the report or an electronic distribution of the report.

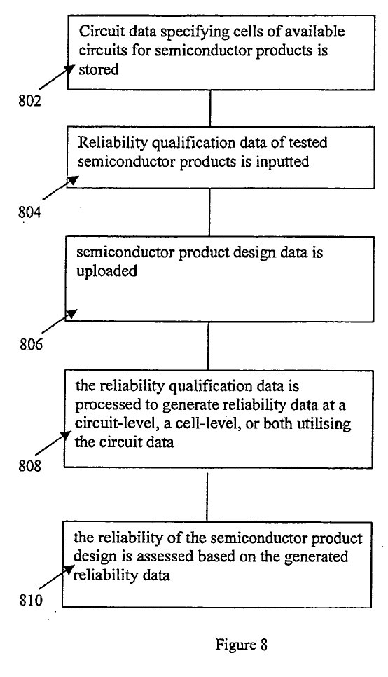

FIG. 8 is a flowchart illustrating a method of assessing reliability of the semiconductor product design. At step 802, circuit data specifying cells of available circuits for semiconductor products is stored. At step 804, reliability qualification data 30 of tested semiconductor products is inputted. At step 806, semiconductor product design data is uploaded. At step 808, the reliability qualification data is processed to generate reliability data at a circuit-level, a cell-level, or both utilizing the circuit data.

At step 810, the reliability of the semiconductor product design is assessed based on the generated reliability data.

The system and method of assessing reliability of a semiconductor product design described may allow a user to assess circuits data and reliability data in a single system or platform both concurrently and simultaneously. On the single system, identification of product or circuits status (at either maturity level or failure) may be carried out for assessment purposes. Products or circuits in each process technology node may also be differentiated using their unique silicon validation and reliability results. Thus, the system and method may assist in assessing the reliability of products. Advantageously, assessing reliability may result in minimization of re-tapeout related to known reliability issues, may save prototyping cost/time as well as may improve a product's time-to-market. The system and method may also provide other functionalities such as generation of reliability reports, linking of reliability data down to a cell level of each circuit and calculating circuit statistics based on reliability data.

Furthermore, the inventors have recognized that, unlike typical cell-based design methodologies, the system and method described utilizes reliability qualification data from manufactured products to assess reliability of e.g., a new product design.

It will be appreciated by a person skilled in the art that numerous variations and/or modifications may be made to the present invention as shown in the specific embodiments without departing from the spirit or scope of the invention as broadly described. The present embodiments are, therefore, to be considered in all respects to be illustrative and not restrictive.

1. A system for assessing reliability of a semiconductor product design, the system comprising:
a first database for storing circuit data specifying cells of available circuits for semiconductor products;
an input unit for input of reliability qualification data of tested semiconductor products;
an uploading unit for uploading semiconductor product design data; and a processor for processing the reliability qualification data to generate reliability data at a circuit-level, a cell-level, or both utilizing the circuit data, and for assessing the reliability of the semiconductor product design based on the generated reliability data.

2. The system as claimed in claim 1, further comprising a second database for storing the generated reliability data.

3. The system as claimed in claim 2, wherein the generated reliability data is stored in the form of a lookup table.

4. The system as claimed in of claim 1; wherein the processor segregates the semiconductor product design into circuits, cells or both for assessing the reliability of the semiconductor product design based on the generated cell-level reliability data.

5. The system as claimed in claim 1 to 4, wherein the input means is a Graphical User Interface (GUI).

6. The system as claimed in claim 1, further comprising 30 a report generator module for outputting reports based on the assessed reliability of the semiconductor product design.

7. The system as claimed in claim 6, further comprising an output Graphical User Interface (GUI) for display.

8. The system as claimed in any one of claim 1 , wherein the 5 processor comprises a security management module for managing user access to the system.

9. The system as claimed in claim 1, further comprising an editing module for editing the circuits data based on a user input.

10. The system as claimed in claim 1, wherein the uploading unit is a file uploader application program.

11. A method of assessing reliability of a semiconductor product design, 15 the method comprising:
storing circuit data specifying cells of available circuits for semiconductor products;
inputting reliability qualification data of tested semiconductor products; uploading semiconductor product design data;
processing the reliability qualification data to generate reliability data at a circuit-level, a cell-level, or both utilizing the circuit data; and
assessing the reliability of the semiconductor product design based on the generated reliability data.

12. A method as claimed in claim 11, further comprising linking the circuit data with statistical information based on a product status.

13. A computer readable data storage medium having stored thereon computer code means for instructing a computer processor to execute a method of assessing reliability of a semiconductor product design, the method comprising:
storing circuit data specifying cells of available circuits for semiconductor products;
inputting reliability qualification data of tested semiconductor products; uploading semiconductor product design data;
processing the reliability qualification data to generate reliability data at a circuit-level, a cell-level, or both utilizing the circuit data; and
assessing the reliability of the semiconductor product design based on the generated reliability data.
